(19) United States
(12) Patent Application Publication
(10) Pub. No.: US 2009/0304202 A1
(43) Pub. Date: Dec. 10, 2009

(54) SOUND AMPLIFICATION SYSTEM

(75) Inventors: Deepak Somasundaram, Bangalore (IN); Tom Flaherty, Petaluma, CA (US)

Correspondence Address: BIRCH STEWART KOLASCH & BIRCH, PO BOX 747, FALLS CHURCH, VA, 22040-0747, US

(73) Assignee: PHONIC EAR INC., Petaluma, CA (US)

(21) Appl. No.: 12/523,286

(22) PCT Filed: Jan. 10, 2008
(86) PCT No.: PCT/EP08/50236

§ 371 Date: Jul. 15, 2009

Related U.S. Application Data
(63) Continuation of application No. 11/653,281, filed on Jan. 16, 2007.

(51) Int. Cl. H04R 27/00; H03F 99/00

(52) U.S. Cl. 381/82; 381/120

(57) ABSTRACT

A classroom sound amplification system adapted for providing information aiding at diagnosing possible erroneous or inappropriate conditions or configuration of the system is disclosed. The system comprises a microphone device converting a voice to a sound signal and connecting to a sound processing device processing the sound signal and generating a processed sound signal, and a speaker device connecting to the sound processing device and converting the processed sound signal to a processed voice. The microphone device, the sound processing device, the speaker device and one or more A/V-devices are connected to or form part of the control device allowing the control device to collect operational information concerning the operation and/or status of devices of the system by monitoring predefined operational a parameters at various points in time.

### FIELD OF INVENTION

This invention relates to a sound amplification system, in particular a classroom amplification system, i.e. a system used for enhancing the sound so as to increase the learning for students, such as a public address sound system or an assistive learning system. The invention relates specifically to the maintenance of such systems. The invention further relates to minimization or cancellation of acoustical feedback in such systems.

### BACKGROUND OF INVENTION

The present account of the prior art relates to one of the areas of application of the invention, classroom sound amplification systems.

Generally, state of the art classroom sound systems comprise a microphone worn by a teacher and connected to an amplifier, which amplifies the teacher's voice and communicates an amplified signal to a set of speakers situated in the classroom. As the teaching format has evolved from classical lectures given from a generally fixed position in front of a blackboard to computer power point presentations and a moving teacher moving around in the classroom, the requirements of a classroom sound amplification system has simultaneously increased. A multitude of technical features can be included in such a system, e.g. features relating to the distribution and quality of sound, such as e.g. acoustical feedback compensation but also other features relating to a combination with stationary or mobile audio and/or visual units. Such combinations can make the system relatively complex.

For example, the movement of the teacher requires the classroom sound amplification system to be able to compensate for acoustical feedback generated when the teacher, for example, moves the microphone closer to one of the speakers.

The troubleshooting of an installed system can be difficult, and e.g. involve drawing the user's attention to checklist's containing typical errors and/or wrong or inappropriate system settings, etc., and if insufficient to solve the problem anyway may require that part of or the whole system is sent in to the manufacturer or to a service site for evaluation. Alternatively, it may require that a technician goes to the place of installation. In some cases, systems thus evaluated are found fully functional, and the conclusion is that the mal-function is due to some sort of inappropriate or erroneous configuration of the system. This is obviously time consuming and costly, and imposes down-time of the system, all of which is degrading the perceived value of the classroom amplification system.

### SUMMARY OF THE INVENTION

An object of the present invention is to provide an improved sound amplification system, e.g. a classroom amplification system overcoming drawbacks of prior art sound systems.

It is a further object to provide a system that is simpler to maintain.

It is a further object of embodiments of the present invention to improve the learning of students in a classroom environment so that a greater number of students benefit from the teaching.

A particular advantage of embodiments of the present invention is to enable the teacher to move freely and un-hindered around amongst the students while the voice is being processed and distributed by the sound amplification system.

A particular feature of embodiments of the present invention is the provision of a transmission of images concurrently with transmission of a teacher's voice.

An object of embodiments of the present invention is to provide a sound system having a simple and effective means for eliminating acoustical feedback, and which requires only a few processing steps.

A particular feature of the present invention is utilization of an understanding of the statistical distribution of a speech signal in the frequency domain.

One or more of the above objects are achieved by a sound amplification system (e.g. a classroom sound amplification system) comprising a microphone device adapted to convert a an acoustical sound (e.g. a voice or a combination of a voice and other sounds, e.g. music) to a (e.g. electric) sound signal and connecting to a sound processing device adapted to process said sound signal and to generate a processed sound signal, and a speaker device connecting to said sound processing device and adapted to convert said processed sound signal to a processed sound, and further one or more Audio- and/or Video-devices and a control device, the control comprising a data processing unit, a memory and optionally a communications interface, wherein the microphone device, the sound processing device, the speaker device and the one or more Audio- and/or Video-devices are connected to or form part of said control device allowing the control device to collect operational information concerning the operation and/or status of various devices of the system (including the A-V-devices) by monitoring predefined operational parameters at various points in time and by storing such information in said memory.

These operational parameters may not only give an indication of malfunction or approaching need for maintenance, but can also provide statistics for normal operation.

Examples of malfunction can e.g. be excessive occurrence of the wireless link going in and out of squelch, multiple feedback detections, distortion detected in the audio-processing, microcontroller or DSP running in faulty or abnormal modes, excessive current draw for amplification, charging attached receivers or intermittent wired connections.

Examples normal functions that can lead to malfunction if not attended to can e.g. be approaching maintenance in the form of replacing rechargeable batteries.

Examples of normal operational parameters that can advantageously be monitored are use-time and use-hours, volume-settings, number of different transmitter signal received, ID of individualized transmitters, which audio-sources are used and more.

The term “processed” is in this context to be construed as amplifying a signal according to a transfer function; i.e. the gain is not necessarily constant throughout a frequency bandwidth, or throughout time. Further, the term “processor” or “processing device/unit” is in this context to be construed as a unit capable of performing a wide range of mathematical processes such as achieved by a microprocessor, a microcontroller, a central processing unit, and/or a digital signal processor. Hence the processor is capable of implementing a transfer function for a sound signal, i.e. providing a required gain in accordance with frequency.

The terms “a” and “an” used in connection with elements of the invention are in this context to be construed as one or more, a plurality, or a multiplicity of elements.

It should be emphasized that the term “comprises/comprising” when used in this specification is taken to specify the presence of stated features, integers, steps or components but does not preclude the presence or addition of one or more other stated features, integers, steps, components or groups thereof.

In an embodiment, one or more Audio- and/or Video-devices comprise a further microphone device or a further speaker device. In an embodiment, one or more Audio- and/or Video-devices comprise a DVD-player or a personal computer with display and/or loudspeaker and/or microphone, a smart board, etc.

In an embodiment, the operational information can be inspected directly (in real time or retrieved at a later point in time) via a display unit or be exchanged with another unit or system, e.g. via a fixed transmission line or a network, e.g. the Internet.

In a particular embodiment, the sound amplification system is a classroom sound or voice amplification system, where a microphone device is worn by a person, e.g. a teacher, who may be stationary or move around in the classroom.

The presence of computing power and memory in a classroom amplification system allows the retrieval of performance data over time of any character, assumed to have an influence on system performance, including some of the following operational information:
Usage patterns
   Use-/down-time, to determine and analyze the use pattern in a particular class room, in a particular period. Systems having use-time below average may indicate lack of training, malfunction, or unawareness of the benefits of the system with the user. Such information is of interest to a technology director or school-administrator looking for efficiencies, or justification for training or further investments in technology.
   How often the system has been muted, to determine how often (or how large a fraction of the time) the teacher's voice has been amplified within the class.
   Charging parameters, e.g. charging curve characteristics, charge-current and battery voltage as a function of time charged, e.g. if charge-current over a certain time does not lead to increased voltage, such information serve as an indicator that batteries need to be replaced. A good (nominally 1.5 V, rechargeable) battery will reach 1.4 V within 60 minutes from the start of charging.
   De-charging parameters, battery-voltage has a typical steep drop shortly before being fully depleted that can be expressed as a ΔV/Δt value. When this drop reaches −5 mV/min., the battery is close to being fully depleted. This, in combination with the information of the charge-cycle can likewise provide information about battery status, and whether or not the cell should be replaced.
   how often (or how large a fraction of the time) other media were run using the system, to determine metrics or trends for the use of multimedia in classrooms,
Incidences of interference: SNR (Signal to Noise Ratio) or similar detections of ‘impurities’ in the processed signal will help determine if sensors and antennas are adequately picking up the signal. An example is to utilize the tone-encoded squelch, for measuring the noise-floor. If the noise-floor exceeds a limit of say 5% of full deviation, then that is an indication of interference or noise being injected into the system, By turning on and off the signal inputs (wireless channels/sensors and aux-in's) and repeating the noise-floor calculation, the most probable cause of interference can be circled in. This can be relayed as a message in either a display on the unit, or a text-message generated into a log-file sent to a pre-determined internet address, or in other ways communicated to the user, the tech-administrator or the manufacturer.
Low modulation of the received signal will indicate that the microphone is too far away from the mouth of the presenter, or the microphone is malfunctioning, an example being the mike-ports being obstructed by some means. A typical system may have 25 KHz as full deviation, meaning the transmitter carrier signal is modulated to it's maximum limit. This will typically correspond to a 90 dB SPL (sound pressure level) at the microphone of the transmitter, and result in compression or clipping occurring. A normal input would, depending on the microphone type, be in the range from 75 to 85 db SPL. Hence—if the modulation is typically below 5 KHz, sampled when speech is present, this low modulation is an indicator of malfunction that can be relayed in manners as described above.
Incidences of feedback will indicate that speakers are not placed in optimal places in the room. This information can also be used to evaluate the effectiveness of the amplification system,
Static noise, noise in the receiver, this can help aid in troubleshooting the installation, such as a failure in the squelch circuit,
Incidences where the microphone went into clipping. When the modulated signal is driven into saturation (full deviation on analog wireless carrier), it can create clipping effects, resulting in distorted signals. This information can be used to inform the presenter of proper use of the microphone, or to lover the gain of microphone pre-amplifier stages.
Settings of user-controls on the system, such status information, which is helpful in evaluating the system and at least some of which is or can be made self-diagnosing, can thus be retrieved either directly from the system memory (or from another storage medium to which the data are transferred), when units are shipped in to a service centre for repairs, or remotely when such data are transmitted to a service centre (e.g. in real time or streamed via a WLAN/Internet connection).

The term ‘streamed’ or ‘streaming’ in connection with an audio or video signal is in the present context taken to mean that the audio or video signal (or file) is being transmitted while it's contents is being presented to the receiver, typically with a certain amount of buffering (as opposed to the situation where an audio or video file is transmitted in full to a receiver before it is presented).

In an embodiment, operational data are collected from a monitored device via a USB interface (or similar standardized communication-interface) to a control device (e.g. a PC or Mac). In an embodiment, data are stored in a log-file on the control device. In an embodiment, operational data are collected from a monitored device via a wired or wireless local area network. In an embodiment, operational data are collected from a monitored device via the Internet, the monitored device having an IP-address assigned.

In an embodiment, the control device is a PC or MAC computer (personal computer). In an embodiment, the control device functions as a media hub of a classroom sound amplification system tying together the various parts of the system and e.g. including a projector and/or a high-bandwidth network connection. This has the advantage that all sorts of content and media can be downloaded, manipulated, created and played (on the relevant device/unit) via the control device. Further, during a lesson—in addition to amplifying the teacher's voice—different media could be controlled and played through the classroom sound amplification system (e.g. computer assisted presentations, audio files, video files, smart board sessions, etc.).

In a particular embodiment, the system is adapted to forward operational information to a predefined receiving unit (e.g. a local or remote service unit or centre). In a particular embodiment, the system is adapted to forward such operational information at regular intervals in time, e.g. once a day (e.g. during idle periods, e.g. nightly, e.g. via e-mail). In a particular embodiment, the system is adapted to forward such operational information automatically based on predefined criteria or the system comprises an activator (e.g. a ‘help button’ implemented in hardware or software) allowing a user to activate such forwarding. In a particular embodiment, the predefined criteria comprise one or more conditions for dysfunction of the system.

In a particular embodiment, the system comprises a set of predefined criteria for the monitored operational parameters representing un-allowed or inappropriate configurations of the system. An un-allowed operational parameter could e.g. be a maximum allowable de-charging rate for battery powered units, a value superseding the maximum value indicating that replacement of batteries are required. Another example could be maximum volume control settings, values superseding the maximum values indicating an improper setup or installation.

In a particular embodiment, the system is adapted to create a system status signal based on a comparison of the monitored operational parameters and said predefined criteria. Such system status signal could indicate whether or not the system is in a state of error, and if so, in which part (or device) such erroneous state is present. In a particular embodiment, the system microcontroller in the control device is configured to go through a self-test mode upon power up, and if certain state-parameters are outside normal limits an error code is generated. In an embodiment, the error code equals the system status signal.

In a particular embodiment, the system is adapted to forward such operational information automatically to a predefined unit or system based on and/or in response to a comparison with said predefined criteria. Such unit or system can be a part of the sound amplification system or located remotely, e.g. at a service centre, where a technician can attend to the information and take proper action.

In a particular embodiment, the system is adapted to create a diagnosis based on a comparison of the monitored operational parameters and said predefined criteria, thereby creating a self-diagnosing system.

In a particular embodiment, the system is adapted to provide that a wearer of a microphone device of the system and whose voice is to be processed and distributed by the system is able to move freely within the normal area of function of the system without being limited in movement by cable wiring to the microphone device and possible other devices integrated therewith.

In a particular embodiment, the classroom sound amplification system is wireless. A wireless system implies that the wearer of the microphone device (e.g. a teacher) and whose voice is to be processed and distributed by the system is able to move freely (including not being limited in movement by cable wiring to the microphone device (and possible other devices integrated therewith, e.g. a sound processing device). In other words, the direct communication from the part of the system carried by a wearer of a microphone device of the system to other parts of the system is wireless.

In a particular embodiment, the system comprises more than one microphone device, e.g. 2, 3, 4, 5 or more. In an embodiment, each microphone can be individually activated in the system, and each individual microphone is associated with a particular person or student. In an embodiment, no more than one microphone device can be active at a given time. In an embodiment, more than one microphone device can be active at a given time. In an embodiment, the system is adapted to process a human voice. In an embodiment, the system is adapted to process a voice or a combination of a voice and other sounds, e.g. music.

In a particular embodiment, the sound processing device comprises a feedback cancellation unit adapted to identify acoustical feedback in said sound signal and to remove said acoustical feedback in said sound signal.

The feedback cancellation unit may comprise a calculating element adapted to calculate a threshold value based on mean magnitude and standard deviation of the sound signal. The feedback cancellation unit may further comprise a FFT element adapted to transform the sound signal into frequency domain, and a peak identification element adapted to identify a peak in the sound signal in frequency domain and to generate a peak signal. The feedback cancellation unit may further comprise a comparator adapted to compare the threshold value with the peak signal and to generate a control signal identifying frequency of the peak. The feedback cancellation unit may further comprise a programmable notch-filter unit adapted to receive the control signal and operable to filter out a bandwidth of the sound signal in accordance with the control signal thereby generating the processed sound signal.

The classroom sound system may, advantageously, utilize the fact that vocal sound has a Gaussian distribution in the time domain and the fact that most energy is of the vocal sound is within one standard deviation from the centre frequency. Hence the classroom sound system is particularly useful in situations where vocal sound is to be amplified such as in a classroom.

The microphone device may comprise a microphone transmitter adapted to transmit the sound signal wirelessly to the sound processing device in accordance with a communication protocol. The communication protocol may be a proprietary protocol or a protocol such as Bluetooth, WLAN, WiMax, Wi-Fi, or other standardized protocols. The microphone transmitter, advantageously, enables the teacher to freely move around in the classroom and provide support for students at their tables or desks. However, having the teacher moving around in the classroom increases the possibility of the occurrence of acoustical feedback since the position of the microphone relative the speaker device may be too close. Hence prior art classroom amplification systems with wireless microphones inherently experience acoustical feedback creating a howling sound from the speakers. The feedback cancellation unit thus, advantageously, ensures dynamic removal of acoustical feedback.

The sound processing device may comprise a sound processing transmitter adapted to transmit the processed sound signal wirelessly to the speaker device in accordance with a communication protocol. The communication protocol may be a proprietary protocol or a protocol such as Bluetooth, WLAN, WiMax, Wi-Fi, or other standardized protocols. The sound processing transmitter thus enables for wireless connection to a speaker device. This further flexibility in movement of the teacher carrying a microphone wirelessly connecting to the sound processing device, which is wirelessly transmitting to a movable speaker device, further increases the possibility for the occurrence of acoustical feedback. Hence the feedback cancellation unit ensures the mobility of the speaker devices as well as the microphone by dynamically removing acoustical feedback when detected.

The speaker device and/or an Audio- and/or Video-device of the system may comprise an interactive white-board. The interactive white-board offers computer-interactive presentation, which offers images together with audio such as the teacher's processed voice (in that speech to text processing software is applied). Having the teacher facing an interactive white-board equipped with speakers further increases the possibility of occurrences of acoustical feedback, which, advantageously, is prohibited by the feedback cancellation unit according to the first aspect of the present invention.

The interactive whiteboard and/or computer can provide visibility to some or all of the before mentioned operational parameters, and allow the presenter un-preceded easy access to monitor or change status of these operational parameters as well as all other operational parameters of the combined audio/visual system. Obvious changes would be to set volume of individual sources, turning on/off auxiliary audio input, or control recording/streaming of presented audio. This will benefit the presenter by allowing focus on one user-interface to the combined audio-visual system.

In a special embodiment the speakers of the system would be built into the interactive whiteboard, for ease of installation and mobility of equipment

The speaker device may comprise a personal computer wirelessly connecting to the sound processing transmitter and/or microphone transmitter and adapted to receive images concurrent to the speaker device generating the processed voice. Hence the personal computer may provide visual support during classes such as, for example, power point shows or other presentational data. The personal computer may comprise a laptop or desktop general purpose computer.

The speaker device may be integral with the personal computer or be external devices plugged to the personal computer. Hence the personal computer allows the teacher to communicate with the students in a classroom by having the microphone device connecting directly to the students' personal computers, while simultaneously presenting visual material either directly, or streamed to the students personal computers.

The personal computer may comprise a wireless receiver connecting to the sound processing transmitter. Hence the wireless receiver may be implemented by a PCMCI card inserted into the personal computer such as WLAN, Wi-Fi, WiMax or Bluetooth. Furthermore the personal computer may be equipped with software-means to record the sound presented by the sound-processing system together with any visual material presented via the interactive whiteboard, thus providing a stored recording of both audio- and visual proceedings of the particular presentation, placed in time-domain.

The personal computer may connect to projecting means adapted to display a visual presentation. The personal computer may further connect to a communications network such as a local area network (LAN), wide area network (WAN), metropolitan area network (MAN), or an internetwork (e.g. the Internet), which communications network is adapted to forward the processed sound signal. The communications network may interconnect the personal computer to a plurality of speaker devices and/or further personal computers. Hence the personal computer may act as a media hub of a classroom.

The personal computer may comprise the sound processing device. The sound processing device may be implemented in the personal computer as a software program.

The programmable notch-filter may comprise a leaky integrator operable to control attack time of said programmable notch-filter. The leaky integrator ensures that the notch-filter gradually reduces the sound signal in the frequency domain in a bandwidth of the notch-filter so that artifacts introduced by steep edged notch-filters are avoided. The leaky integrator is computationally efficient for the sound system since it requires only three mathematical operations.

Further, the leaky integrator may be operable to control the attack times of the programmable notch-filter in accordance with frequency. That is, the leaky integrator may be adapted to be operable having a first attack time for a first frequency bandwidth and having a second attack time for a second frequency bandwidth. Thus the leaky integrator may e.g. be operable having a long attack time in the high frequency part of said sound signal in said first frequency bandwidth and having a short attack time in the low frequency part of said sound signal in said second frequency bandwidth.

The term “attack time” is in this context to be construed as the time it takes for the programmable notch-filter from receiving a control signal to fully engaging the filter. Further, “attack time” is in this context to be construed as similar to “release time” being the opposite, namely the time it takes for the programmable notch-filter from receiving a control signal to fully disengaging the filter.

The processor (or sound processing device) may further comprise a counter unit adapted to count a number of frequencies of said sound signal in the frequency domain having magnitudes above said threshold value. The counter unit may be adapted to provide a gain control signal to said processor when the count of said frequencies is above a predetermined number. Hence, the processor when receiving the gain control signal may reduce gain throughout the frequency spectrum. This is, particularly, advantageous since by identifying a plurality of frequencies in the sound signal in the frequency domain may demonstrate an acoustical feedback is present. For example, the predetermined number may be in the range between 2 to 10 such as 3.

The programmable notch-filter may be operable to establish a number of parallel notch-filters each having a selected operating bandwidth. Obviously, any number of parallel notch-filters may be established each having a selected operating bandwidth and centre frequency; however, the number may be limited to the predetermined number defined above.

The programmable notch-filter may be operable to receive the sound signal in the time domain or to receive the sound signal in the frequency domain. The configuration of the programmable notch-filter is thus not limiting to the sound system.

In addition, the programmable notch-filter may comprise amplifying means adapted to amplify the sound signal in accordance with a predetermined transfer function. The programmable notch-filter may be implemented as an active filter such as an infinite impulse response filter.

In an aspect of the invention a method of operating a sound amplification system is provided, the method comprising

a) providing a microphone device adapted to convert an acoustical sound to an electrical sound signal,

b) providing a sound processing device adapted to process said sound signal and to generate a processed sound signal,

c) providing a speaker device adapted to convert said processed sound signal to a processed sound,

d) providing one or more Audio- and/or Video-devices, and

e) providing a control device comprising a data processing unit, a memory and optionally a communications interface,

f) connecting the microphone device, the sound processing device, the speaker device and the one or more Audio- and/or Video-devices to said control device, thereby allowing the control device to collect operational information concerning the operation and/or status of various devices of the system;

g) monitoring predefined operational parameters of said devices at various points in time and storing such information in the memory of the control device.

In a particular embodiment, the system comprises a communications interface allowing the system (e.g. the control device) to communicate with local or remote units or systems, e.g. a service centre.

In a particular embodiment, the system is adapted to forward the operational information to a predefined receiving unit or system.

In a particular embodiment, a set of predefined criteria for the monitored operational parameters representing un-allowed or alarming values or inappropriate configurations of the system is defined.

In a particular embodiment, said set of predefined criteria is stored in the memory of the control device.

In a particular embodiment, a system status signal based on a comparison of the monitored operational parameters and said predefined criteria is created.

In a particular embodiment, said operational information is forwarded automatically to a predefined unit or system in response to a comparison with said predefined criteria.

In a particular embodiment, a system diagnosis is created based on a comparison of the monitored operational parameters and said predefined criteria, thereby creating a self-diagnosing system.

In a particular embodiment, a wearer of a microphone device of the system and whose voice is to be processed and distributed by the system is able to move freely within the normal area of function of the system without being limited in movement by cable wiring to the microphone device and possible other devices integrated therewith.

In a particular embodiment, the direct communication from a part of the system carried by a wearer of a microphone device of the system to other parts of the system is wireless.

In a particular embodiment, the operations performed by the microphone device, the sound processing device and the speaker device comprise:

(a) converting an acoustical sound to an electrical sound signal,

(b) calculating a threshold value based on mean magnitude and standard deviation of said sound signal,

(c) transforming said sound signal into frequency domain,

(d) identifying a peak in said sound signal in frequency domain and generating a peak signal,

(e) comparing said threshold value with said peak signal and generating a control signal identifying frequency of said peak when said peak signal is above said threshold value,

(f) filtering out a bandwidth of said sound signal according to said control signal thereby generating a filtered sound signal,

(g) processing said filtered sound signal and generating a processed sound signal,

(h) communicating said processed sound signal to a speaker device,

(i) converting said processed sound signal to a processed acoustical sound.

In an aspect of the invention use of a system according to the invention and as described above, in the detailed description and in the claims is provided.

In a particular embodiment the system is used as a classroom sound amplification system. In a particular embodiment the sound includes a voice.

### BRIEF DESCRIPTION OF THE DRAWINGS

The above, as well as additional objects, features and advantages of the present invention, will be better understood through the following illustrative and non-limiting detailed description of preferred embodiments of the present invention, with reference to the appended drawing, wherein:

FIG. 1, shows a block diagram of a sound system according to a first embodiment of the present invention;

FIG. 2, shows a block diagram of a sound processor for the sound system according to a first and presently preferred embodiment of the present invention;

FIG. 3, shows a further block diagram of a sound processor for the sound system according to a second embodiment of the present invention;

FIG. 4, shows a further block diagram of a sound processor for the sound system according to a third embodiment of the present invention;

FIG. 5, shows a further block diagram of a sound processor for the sound system according to a fourth embodiment of the present invention;

FIG. 6, shows an overview of a classroom amplification system according to an embodiment of the present invention;

FIG. 7, shows a block diagram of classroom amplification system according to an embodiment of the present invention; and

FIG. 8 shows a basic configuration of a sound amplification system according to an embodiment of the invention.

### DETAILED DESCRIPTION OF PREFERRED EMBODIMENTS

In the following description of the various embodiments, reference is made to the accompanying figures, which show by way of illustration how the invention may be practiced. It is to be understood that other embodiments may be utilized and structural and functional modifications may be made without departing from the scope of the present invention.

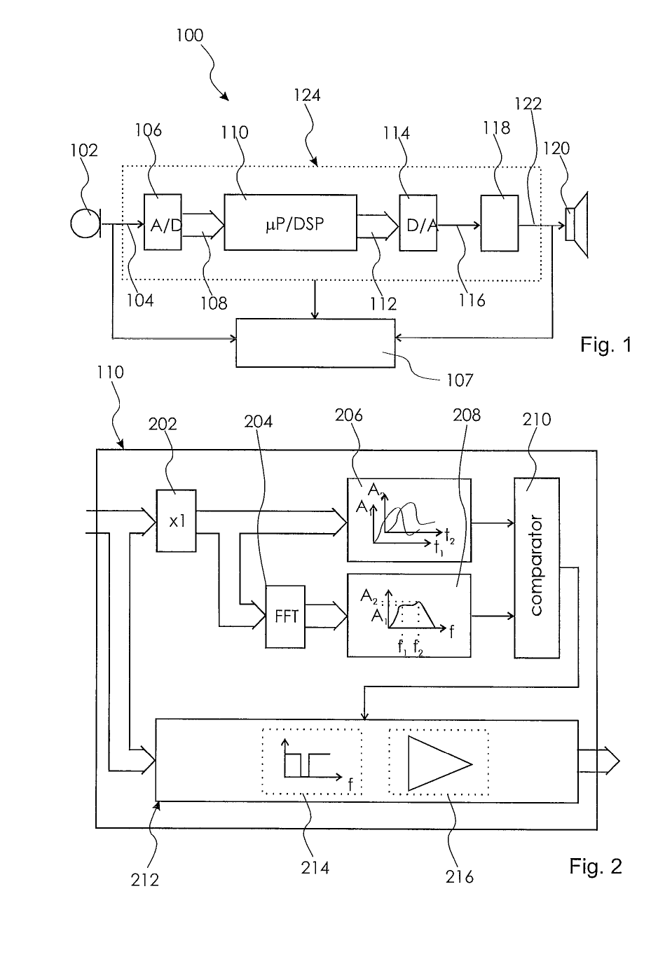

FIG. 1, shows a block diagram of a sound system according to the first embodiment of the present invention and designated in entirety by reference numeral 100. The sound system 100 comprises a microphone unit 102 converting a sound to an analogue electrical sound signal. The analogue electrical sound signal is communicated through a first communication path 104 to an analogue-to-digital (A/D) converter 106, which converts the analogue electrical sound signal into a digital sound signal. The digital sound signal is communicated through a second communication path 108 to a sound processor 110, which processes the digital signal in accordance with a predetermined transfer function. The second communication path 108 may be a multi-channel bus. The sound processor 110 generates a processed digital signal and communicates this through a third communication path 112 to a digital-to-analogue (D/A) converter 114. The third communication path 112 may be identical to the second communication path 108 i.e. a controlled multi-channel bus. The D/A converter 114 converts the processed digital signal into a processed analogue signal and communicates this through a fourth communication path 116 to a driver 118. Finally, the driver 118 is connected to a loud speaker 120 through a fifth communication path 122 and is adapted to drive the loud speaker 112 to present a processed sound.

A large part of the sound system 100 may in fact be implemented as integrated elements so that the sound system 100 comprises the microphone unit 102, the speaker unit 120 and a digital signal processor 124.

A control device 107 for gathering operational information (such as parameters that may be used to judge the operational status of the device in question) of the devices of the system is connected to each of the monitored devices.

The sound processor 110 as shown in FIG. 2 comprises an input buffer unit 202 adapted to buffer the digital signals into a number (N) of frames (each frame containing q samples of the digitized signal (q e.g. being 128 or 256 or 512 or more) at a given time instant, n), which are communicated to a FFT unit 204 transforming the frames into frequency domain signals and to a threshold calculation unit 206 adapted to calculate a threshold value from the frame based on mean magnitude (m) and standard deviation (σ) of the frames. For example the threshold value may be determined in accordance with formula 1 below.

Threshold_value=m+α·σ (Formula 1),

where “m” is the mean magnitude of the frame, “α” is a multiplication factor and “σ” is standard deviation of the frame. The calculation of the threshold value may further be adjusted by a bias. The multiplication factor “α” may have any real number, e.g. in the range from 0.5 to 5, such as between 1 and 3, such as between 1.5 and 2.5; however the presently preferred number is 2, since this provides for most of the energy of the frame if the frame contain vocal information.

The transformed frame is forwarded from the FFT unit 204 to a peak identification unit 208 adapted to identify peaks in the transformed frame and to generate a peak signal for each peak identified in the transformed frame. The peak signal provides information of magnitude and frequency of the peak. The peak identification unit 208 may be configured to identify any number of peaks such as in the range one to ten, for example identifying the three largest peaks in each transformed frame. The peak identification unit 208 may comprise a counter for counting number of peaks and may be adapted to generate a flag signal when the number of peaks identified equals a pre-selected number.

The threshold calculation unit 206 generates a threshold signal for each frame and forwards the threshold signal to a comparator unit 210, which compares the threshold signal to the peak signals received from the peak identification unit 208.

The calculation of the mean magnitude of the frequency spectrum in a frame may advantageously be established by a squared addition of the real and imaginary parts of the digital signals. Further, the calculation of the mean magnitude of the digital signals may advantageously be established by a vector magnitude computation such as suggested by Richard G. Lyons in “Understanding Digital Signal Processing” 2nd edition (the αMax+βMin method). It should be understood that any calculation or estimation know to a person skilled in the art may be employed.

The comparator unit 210 generates a filter control signal in case the peak signal is greater than the threshold value, which filter control signal is forwarded to a filter/amplifier unit 212. The filter/amplifier unit 212 comprises a programmable notch-filter 214 and an amplifier 216, and is adapted to receive the digital sound signal and filter the digital sound signal according to the filter control signal by means of the programmable notch-filter 214, and to amplify the potentially filtered digital sound signal according to a predetermined transfer function by means of the amplifier 216. In this context the term “amplify” is to be construed as increasing or decreasing any particular frequency regions.

The filter/amplifier unit 212 may be implemented as an active filter such as an infinite impulse response (IIR) filter.

The programmable notch-filter 214 may comprise a leaky integrator adapted to provide a gradual engagement of the notch-filter 214 so as to avoid artifacts caused by the notch-filter's 214 sharp edges to be generated. For example, the leaky integrator may be operable so that the effect of the notch-filter is engaged and disengaged slowly. The leaky integrator may be implemented by any means know to a person skilled in the art.

In case the peak identification unit 208 identifies a maximum number of peaks within a frame the comparator 210 generates an alert signal, which causes the filter/amplifier unit 212 to reduce gain of the amplifier 216. The effect of the reduction of the gain is monitored on the following frames. That is, if the peak identification unit 208 fails to identify new peaks in the next frames then the gain is gradually increased.

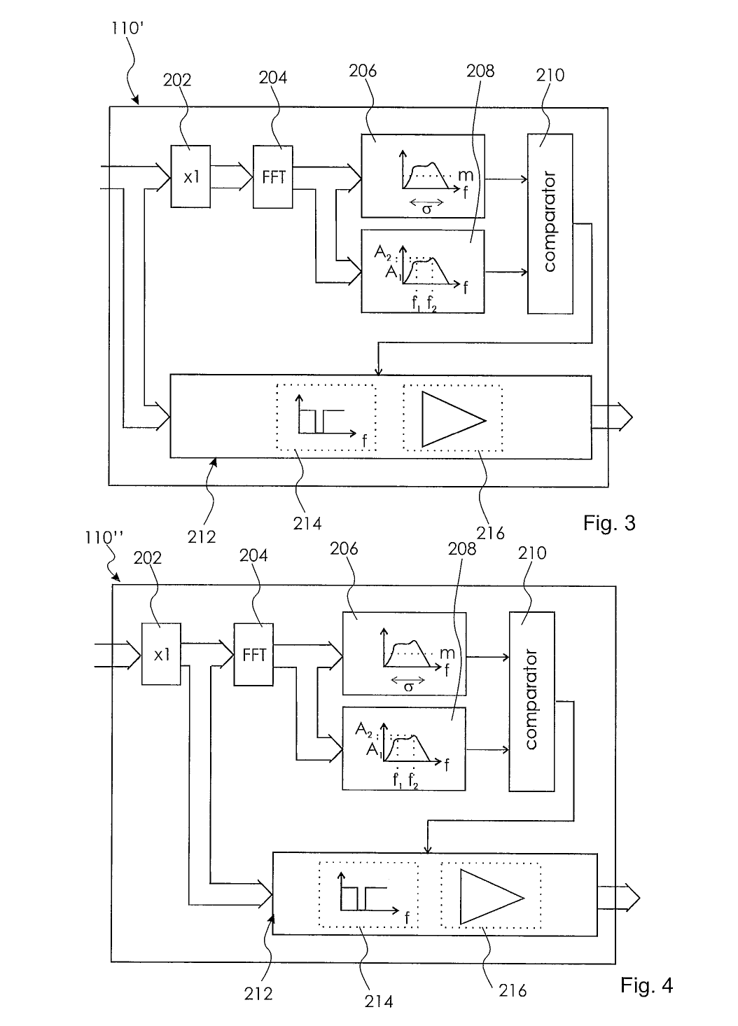

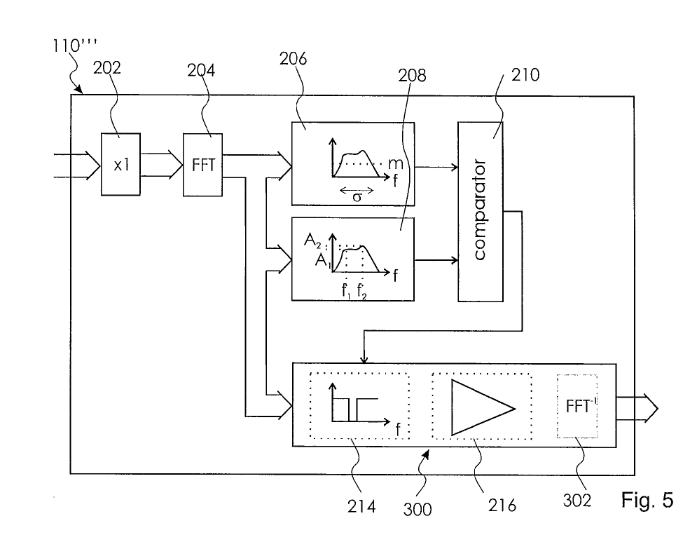

FIG. 3, shows a block diagram of a sound processor 110′ according to a second embodiment of the present invention, which comprises the same elements of the sound processor 110 and these are referenced by the same numerals. The sound processor 110′ differs from the sound processor 110 by having the FFT unit 204 transforming the frames into frequency domain signals, which are then communicated to the threshold calculation unit 206 in this case being adapted to calculate a threshold value from tile frame based on mean magnitude and standard deviation of the frequency spectrum of the frame. Each frame is analyzed in the frequency domain, where an approximation to an appropriate distribution, e.g. a Gaussian distribution, is made, from which the mentioned mean magnitude (m) and standard deviation (σ) of the frames are calculated. The threshold may be calculated according to formula 1 above. Significant frequency content outside the threshold is considered to be feedback.

FIG. 3, shows a block diagram of a sound processor 110″ according to a second embodiment of the present invention. The sound processor 110′ comprises the same elements of the sound processor 110 and 110′ and these are referenced by the same numerals. The sound processor 110″, however, differs from the sound processor 110′ by having the filter/amplifier unit 212 receive frames from the buffer unit 202 and thus perform filtering and amplifying operations on the frames rather than directly on the digital sound signal.

FIG. 4, shows a further block diagram of a sound processor 110′″ according to a third embodiment of the present invention. The sound processor 110′″ comprises the same elements of the sound processors 110, 110′ and 110″ and these are referenced by the same numerals. The sound processor 110″, however, differs from the sound processors 110 and 110′ by having a filter/amplification unit 300 receiving the sound signal in the frequency domain from the FFT unit 204 and thus performing the filtering and amplifying operations on the sound signal in the frequency domain rather than on the digital sound signal or on the frames. The filter/amplification unit 300 further comprises an inverse FFT unit 302 for inverting the processed sound signal in the frequency domain back into a processed sound signal in the time domain.

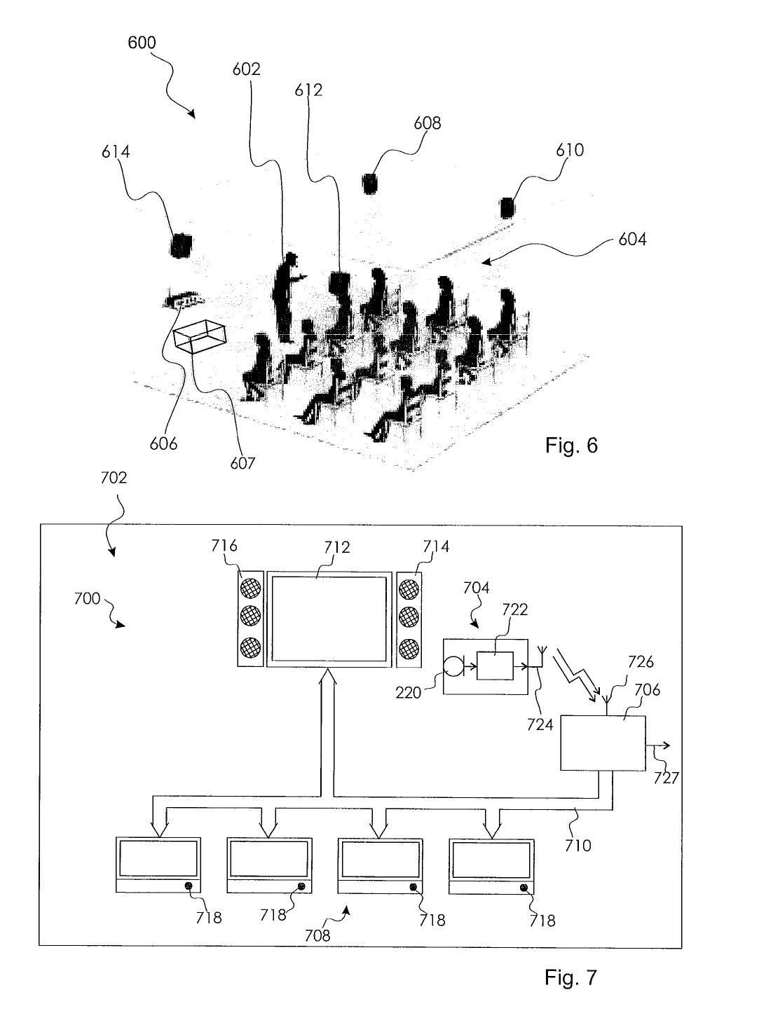

FIG. 6 shows a classroom designated in entirety by reference numeral 600. In the classroom 600 a teacher 602 speaks to an audience of students 604. The teacher 602 carries a microphone device around the neck or attached on a collar of a coat or shirt. The microphone device converts the sound from the teacher 602 to an electric sound signal. The microphone device comprises a transmitter for transmitting the sound signal to a signal processing device 606 receiving the sound signal and performing processing of the sound signal e.g. filtering and amplification. The signal processing device 606 may comprise a transmitter for (wirelessly) transmitting the processed sound signal to speaker devices 608, 610, 612 and 614. Alternatively or additionally, the signal processing device 606 may forward the processed signal to the speaker devices 608, 610, 612 and 614 by wire. The sound system comprises a control device 607 for monitoring the operational history and status of other devices of the system. The control device is electrically or optically connected to other devices of the system to be monitored either via electrical or optical wiring or via wireless connections (e.g. radio frequency or infra red light communication). The signal processing device 606 may e.g. be a part of the control device 607, the processing functions possibly being implemented as a software routine run on said control device, e.g. a PC. The control device is connected to a service centre via a dedicated connection or via a network.

FIG. 7, shows a classroom amplification system according to an embodiment of the present invention and designated in entirety by reference numeral 700. The classroom amplification system 700 positioned in a classroom 702 comprises a wearable microphone unit 704 connecting wirelessly to a control device (here a computer) 706 acting as a hub for a plurality of computers 708. Alternatively the connection between microphone unit and computer may be wired. The computer 706 connects to the plurality of computers 708 through a communications bus 710, which may be implemented as a hardwired local area network or a wireless local area network, such as Bluetooth, Wi-Fi or WiMax. The microphone unit 704 may also directly connect wirelessly to a plurality of students' personal computers or ultra mobile personal computers (UMPC), acting as local speakers and/or storage devices. The plurality of computers 708 may, for example, connect to the communications bus 710 by means of a PCMCI card.

The communications bus 710 may further connect to a displaying means 712, such as a projector or an intelligent whiteboard also known as smart board. The displaying means 712 may be utilized for presentation of images or text relating to the teaching of students. For example, the teacher may utilize the displaying means 712 for presentation of a power point show of text and/or pictures illustrating the subject to be taught. The displaying means 712 comprise one or more speaker units 714 and 716 presenting the processed voice of the teacher or additional audio determined by the teacher. For example, the teacher may desire to illustrate a certain pronunciation of a word or a particular piece of music and include this in the presentation.

Similarly, the plurality of computers 708 may each comprise a speaker unit 718 presenting the processed voice of the teacher or additional audio determined by the teacher.

The microphone unit 704 comprises a microphone 720 for converting the voice of the teacher to a sound signal, a sound processing device 722, such as a digital signal processor, for processing the sound signal in accordance with a transfer function, and an antenna 724 wirelessly transmitting the processed sound signal to the computer 706 via antenna 726.

The control device 706 (here a computer such as a PC) is connected to other devices either via wired or wireless connections to monitor their operational status. The operational information is e.g. gathered at regular intervals in time, e.g. once every hour, and stored in a memory of the control device. A table of un-acceptable operational values of relevant parameters for each of the monitored devices of the system is stored in a memory of the control device. At certain intervals in time, e.g. once every hour, the stored values of the gathered operational information are compared to the un-acceptable operational values of relevant parameters for each of the monitored devices. In case of one or more of the operational parameters falling in an un-acceptable range, such parameter(s) and the relevant device(s) are identified and an alarm is flagged. A message, at least containing the identified parameter(s) and device(s) is transmitted to a service centre for evaluation by a technician, possibly together with information on the configuration of the system, and further operational information, e.g. a number (e.g. 10) of the last stored sets of operational parameters (for facilitating the debugging job of the technician).

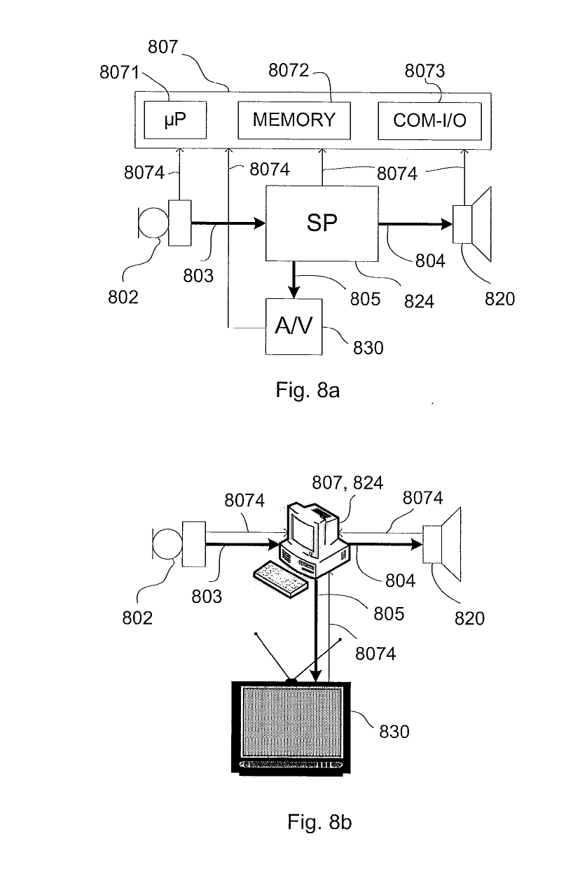

FIG. 8a shows a basic configuration of a sound amplification system according to an embodiment of the invention comprising a microphone device 802 adapted to convert an acoustical sound to an electrical sound signal 803 and connecting to a sound processing (SP) device 824 adapted to process the sound signal and to generate a processed sound signal 804, and a speaker device 820 connecting to the sound processing device 824 and adapted to convert the processed sound signal 804 to a processed sound, and further an Audio- and/or Video-device (A/V) 830 and a control device 807. The control device 807 comprises a data processing unit (μP) 8071, a memory (MEMORY) 8072 and optionally a communications interface (COM-I/O) 8073. The microphone device 802, the sound processing device 824, the speaker device 820 and the A/V-device 830 are connected (via wired or wireless connections 8074) to the control device 807 allowing the control device 807 to collect operational information concerning the operation and/or status of the various devices of the system by monitoring predefined operational parameters at various points in time and by storing such information in the memory 8072 of the. The memory may alternatively be physically located in any other of the units which are mutually connected. A connection to other units or servers may be established via wired or wireless connections using the communications interface 8073. The operational information stored in the memory 8072 may e.g. be transferred to another unit or server via such connection, optionally via a communications network, e.g. the Internet.

FIG. 8b shows an alternative embodiment of the invention, wherein the control unit 807 and the sound processing unit 824 are integrated in the same unit, here shown as a personal computer (PC) . The A/V unit 830 is here exemplified by a TV-set (possibly comprising a DVD or other video player). The electrical sound signal picked up by the microphone unit (typically adapted to be worn by a person, e.g. a teacher) is transmitted by the microphone unit (wired or preferably wirelessly, electrically or optically) to the PC, where a processing of the signal from the microphone can be performed before the processed sound signal is transmitted (wired or preferably wirelessly, electrically or optically) to one or more speakers and to the TV-set. Operational parameters are gathered by the PC from the monitored units of the system via connections 8074. A connection to a local area network or the Internet can be established via the PC, e.g. to transfer the gathered operational parameters for evaluation at a technical service centre. Preferably the system is adapted to be able to receive instructions from another unit or server via the communications interface 8073 of control unit 807, e.g. to change one or more settings of the system.

Generally, state of the art classroom sound systems involve a microphone worn by a teacher and wirelessly connected to an amplifier, which amplifies the teacher's voice and communicates an amplified signal to a set of speakers situated in the classroom (or possible in another room, physically separate from the classroom where the teacher is located).

To establish the wireless link, different technologies have been used over time. For convenience and cost reasons most often common commercially available wireless technologies from providers of RF-components or RF-circuits are used. Examples of classic technologies are analog modulated technologies, the carrier-wave typically being either an RF (radiofrequency) or IR (infrared). These are characterized by being low-complexity, in-expensive proven solutions, offering simple on-way communication links.

As new and more advanced wireless technologies are being commercially available, these have also found their way into the classrooms sound systems.

The global drive for more and more wireless communication lines, with higher and higher density of users, are putting ever increasing pressure on bandwidth, speed, and cost. The classical technologies do not meet these requirements, and a plethora of new digital wireless technologies have emerged in the past decade. The sheer volume of products these technologies are used in is driving the cost down of these very sophisticated technologies. Examples of these technologies are Bluetooth, DECT, IEEE.802.11-compliant technologies, WiBree, ZigBee, etc. And more will come.

It is therefore a natural development that some of these technologies also find use in classroom sound systems.

What they can offer is hassle-free set-up in high density installations, like a school-wide installation. These classrooms are often in need of several channels for team-teaching and student pass-around microphones, which is where the digital technology offers an advantage.

These technologies are most often having a bi-directional exchange of control signals that “negotiates” the communication protocol between the units set up to communicate with each other. Should disturbance occur in the current band/timeslot, they can agree to move to a un-disturbed place in the ether. Likewise audio can be exchanged in both directions. Obviously the teacher's voice can be carried over the wireless link. But the microphone worn by the teacher can also perform as a receiver, receiving classroom activity remotely, response from student pass-around microphones or team teaching units, or receive audio passed through the classroom sound system from external sources.

Some preferred embodiments have been shown in the foregoing, but it should be stressed that the invention is not limited to these, but may be embodied in other ways within the subject-matter defined in the following claims.

1-52. (canceled)

53. A sound amplification system comprising a microphone device adapted to convert an acoustical sound to an electrical sound signal and connecting to a sound processing device adapted to process said sound signal and to generate a processed sound signal, and a speaker device connecting to said sound processing device and adapted to convert said processed sound signal to a processed sound, and further one or more Audio- and/or Video-devices and a control device, the control device comprising a data processing unit, a memory and optionally a communications interface, wherein the microphone device, the sound processing device, the speaker device and the one or more Audio- and/or Video-devices are connected to or form part of said control device allowing the control device to collect operational information concerning the operation and/or status of various devices of the system by monitoring predefined operational parameters at various points in time and by storing such information in said memory.

54. A wireless classroom sound amplification system according to claim 53 wherein said operational information include information on one or more of the following items usage patterns, e.g.
use-/down-time,
how often the system was muted,
charging and de-charging parameters, e.g. how long time it was charged,
how often other media were run using the system,
incidences of interference,
degree of modulation of the received electrical sound signal
incidences of feedback,
amount of static noise,
incidences where microphone went into clipping
settings of user-controls on the system,

55. A system according to claim 53 adapted to allow the operational information to be presented directly via a display unit of the system or to be exchanged with another unit or system.

56. A system according to claim 53 wherein the control device is a personal computer.

57. A system according to claim 53 wherein the control device functions as a media hub of the system tying together the various parts of the system.

58. A system according to claim 53 wherein the system is adapted to forward said operational information to a predefined receiving unit.

59. A system according to claim 53 comprising a set of predefined criteria for the monitored operational parameters representing un-allowed or inappropriate configurations of the system.

60. A system according to claim 59 wherein the system is adapted to create a system status signal based on a comparison of the monitored operational parameters and said predefined criteria.

61. A system according to claim 59 wherein the system is adapted to forward such operational information automatically to a predefined unit or system based on a comparison with said predefined criteria.

62. A system according to claim 59 wherein the system is adapted to create a diagnosis based on a comparison of the monitored operational parameters and said predefined criteria, thereby creating a self-diagnosing system.

63. A system according to claim 53 wherein the system comprises an activator implemented in hardware or software from which the forwarding of such operational information to another unit or system can be initiated.

64. A system according to claim 53 wherein the direct communication from the part of the system carried by a wearer of a microphone device of the system to other parts of the system is wireless.

65. A system according to claim 56 wherein said personal computer further connects to a communications network, and wherein said communications network interconnects the personal computer to a plurality of speaker devices, Audio- and/or Video-devices and/or further personal computers.

66. A system according to claim 56 wherein said personal computer comprises said sound processing device.

67. A system according to claim 66, wherein said sound processing device is implemented in the personal computer as a computer program.

68. A method of operating a sound amplification system comprising
a) providing a microphone device adapted to convert an acoustical sound to an electrical sound signal,
b) providing a sound processing device adapted to process said sound signal and to generate a processed sound signal,
c) providing a speaker device adapted to convert said processed sound signal to a processed sound,
d) providing one or more Audio- and/or Video-devices, and
e) providing a control device comprising a data processing unit, a memory and optionally a communications interface,
f) connecting the microphone device, the sound processing device, the speaker device and the one or more Audio- and/or Video-devices to said control device, thereby allowing the control device to collect operational information concerning the operation and/or status of various devices of the system,
g) monitoring predefined operational parameters of said devices at various points in time and storing such information in the memory of the control device.

69. A method according to claim 68 wherein a set of predefined criteria for the monitored operational parameters representing un-allowed or inappropriate parameters or configurations of the system is defined and stored in the memory of the control device.

70. A method according to claim 69 wherein a system status signal based on a comparison of the monitored operational parameters and said predefined criteria is created.

71. A method according to claim 69 wherein said operational information is forwarded automatically to a predefined unit or system in response to a comparison with said predefined criteria.

72. A method according to claim 69 wherein a system diagnosis is created based on a comparison of the monitored operational parameters and said predefined criteria, thereby creating a self-diagnosing system.
